(19) United States
(12) Patent Application Publication
(10) Pub. No.: US 2010/0194387 A1
(43) Pub. Date: Aug. 5, 2010

(54) MAGNETORESISTANCE SENSOR AND METHOD OF OPERATING A MAGNETORESISTANCE SENSOR

(75) Inventors: Stefan Butzmann, Beilstein (DE); Marcus Prochaska, Pattensen (DE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/678,541

(22) PCT Filed: Aug. 27, 2008
(86) PCT No.: PCT/IB08/53449

§ 371 Date: Mar. 17, 2010

(30) Foreign Application Priority Data
Sep. 25, 2007 (EP) 07117124.3
Aug. 27, 2008 (IB) PCT/IB2008/053449

(51) Int. Cl. G01R 33/02

(52) U.S. Cl. 324/252

(57) ABSTRACT

A magnetoresistive sensor system (400) is provided, wherein the system comprises a magnetic field source (402), a magnetoresistive sensor (403) having an easy axis, and a differentiation element (404), wherein the magnetic field source (402) is adapted to emit an auxiliary magnetic field generated from an oscillating input signal (401), wherein the auxiliary magnetic field is orthogonal to the easy axis of the magnetoresistive sensor (403), wherein the magnetoresistive sensor (403.) is adapted to sense a signal associated to a superposition of an external magnetic field and the auxiliary alternating magnetic field, and wherein the differentiation element (404) is adapted to differentiate the sensed signal.

### FIELD OF THE INVENTION

The invention relates to a magnetoresistance sensor.

The invention further relates to a method of operating a magnetoresistance sensor.

Moreover, the invention relates to a program element.

Further, the invention relates to a computer-readable medium.

### BACKGROUND OF THE INVENTION

Magnetoresistance or magnetoresistive sensors like anisotropic magnetoresistance sensors (AMR) or giant magnetoresistance sensors (GMR) are widely used nowadays. For example, AMR sensors are key-building blocks in many automotive applications, e.g. for antilock braking systems (ABS), engine management, transmission or security systems. Especially in the field of automotive transmission a large air gap capability is required.

Typically, magnetoresistive sensors for rotational speed measurements are linearized by a Barber pole construction. Since Barber pole sensors possess two stable output characteristics a bias magnet is necessary to prevent flipping between positive and negative magnetization directions. However, the auxiliary field Hₓ in x-direction, i.e. parallel to the easy axis of the magnetoresistive sensor, provided by the bias magnet reduces the sensitivity as shown in the following equation:

$$\frac{d {R}_{sensor}}{d H} \sim \frac{1}{{H}_{0} + {H}_{x}} \qquad ( 1 )$$

A main disadvantage of Barber pole sensors is reduced sensitivity caused by this auxiliary field. Furthermore, for increasing air gaps the output signal of the sensor head decreases which leads to heavy requirements for the signal processing and conditioning units of smart sensor systems. Thus, state of the art AMR speed sensors equipped with standard magnets consisting of iron, ferrite, or AlNiCo-alloy are not able to provide air cap capabilities which are required in many fields of applications such as automotive transmission systems.

Thus, there may be a need to provide a magnetoresistive sensor having an improved sensitivity.

### SUMMARY OF THE INVENTION

It is an object of the invention to provide a magnetoresistive sensor system having an improved sensitivity and a method of operating the same.

In order to achieve the object defined above, a magnetoresistive sensor system, a method of operating a magnetoresistive sensor system, a program element, and a computer-readable medium according to the independent claims are provided.

According to an exemplary embodiment a device a magnetoresistive sensor system is provided, wherein the system comprises a magnetic field source, a magnetoresistive sensor having an easy axis, and a differentiation element, wherein the magnetic field source is adapted to emit an auxiliary magnetic field from an oscillating input signal, wherein the auxiliary magnetic field is orthogonal to the easy axis of the magnetoresistive sensor, wherein the magnetoresistive sensor is adapted to sense a signal associated to a superposition of an external magnetic field and the auxiliary alternating magnetic field, and wherein the differentiation element is adapted to differentiate the sensed signal. In particular, the magnetoresistive sensor may be a non-linearized magnetoresistive sensor, e.g. may not have linearized characteristics like a Barber pole sensor as known in the prior art. In particular, the differentiation element may be adapted to perform a differentiation in time of the sensed signal. The auxiliary field may also be called exciting field.

According to an exemplary embodiment a method of linearizing a sensor transfer function of a magnetoresistive sensor is provided, the method comprises generating an auxiliary magnetic field orthogonal to an easy axis of the magnetoresistive sensor, sensing a signal associated to a superposition of an external magnetic field and the auxiliary alternating magnetic field, and differentiating the sensed signal. In particular, the differentiation may be performed by using a differentiation element.

According to an exemplary embodiment a program element is provided, which, when being executed by a processor, is adapted to control or carry out a method according to an exemplary embodiment.

According to an exemplary embodiment a computer-readable medium is provided, in which a computer program is stored which, when being executed by a processor, is adapted to control or carry out a method according to an exemplary embodiment.

Such a provision of a differentiation of the sensed signal of a magnetoresistive sensor by an additional alternating field perpendicular to the easy axis of the magnetoresistive sensor may improve the sensitivity of the magnetoresistive sensor system. In this case the sensitivity of the magnetoresistive sensor system may only be limited by the accuracy of time measurement. Therefore, it may be possible to provide a larger sensing distance, i.e. it may be possible to implement a larger air gap which may be a key requirement for automotive transmission applications. Such an improved sensitivity of a magnetoresistive sensor may also open up new fields of application. In particular, compared to the known Barber pole sensor the saving of the additional bias magnet may lead to reduced production costs. In general such a magnetoresistive sensor system may be used in rotational speed sensors in the automotive sector. Due to the increased sensitivity it may be possible to reliable measure weak magnetic fields. In particular, a magnetoresistive sensor system according to an exemplary embodiment may provide a phase modulation of the signal to be sensed.

A gist of an exemplary aspect of the invention may be seen in the fact that the sensed signal is quasi phase modulated by using a differentiation element. Thus, the measurement of weak magnetic fields may be performed by a duty cycle analysis. To provide a signal where the duty cycle corresponds to the magnitude of an external magnetic field to be measured, an alternating excitation of the sensor element as well as an adequate signal pre-processing may be performed. For the excitation an auxiliary or exciting magnetic field is used, which excites the magnetoresistive sensor and is superimposed to the external magnetic field to be measured. Thus, has an orthogonal direction than the known auxiliary magnetic fields used for Barber pole sensors to suppress flipping. The exciting magnetic field has a polarization which is orthogonal to the easy axis of the magnetoresistive sensor. Such an exciting magnetic field may be generated by a coil which is implemented in a chip the magnetoresistive sensor itself is implemented. In particular, the magnetoresistive sensor may be formed by a non-linear element, i.e. a magnetization sensor having a non-linear transfer function, so that the external field may modulate the amplitude of the excitation. Starting from this amplitude modulated excitation signal a new signal may be derived, where the duty cycle represents the magnitude of the external magnetic field. In this case the sensitivity of the magnetoresistive sensor system may only be limited by the accuracy of time measurement.

Summarizing, the basic embodiment of an exemplary magnetoresistive sensor system may be the provision of a magnetic field source which provides or generates an auxiliary magnetic field which is an alternating field and has a direction which is orthogonal to the easy axis of a magnetoresistive sensor of the magnetoresistive sensor system. The modulated signal may then be processed by a differentiation element in order to achieve a phase modulated sensor signal.

Next, further exemplary embodiments of the invention will be described.

In the following, further exemplary embodiments of the magnetoresistive sensor system will be explained. However, these embodiments also apply for the method of linearizing a sensor transfer function of a magnetoresistive sensor, for the program element and for the computer-readable medium.

According to another exemplary embodiment of the magnetoresistive sensor system the magnetoresistive sensor is an anisotropic magnetoresistive sensor and/or and giant magnetoresistive sensor.

According to another exemplary embodiment the magnetoresistive sensor system further comprises a mixer adapted to mix the differentiated signal and the oscillating input signal. In particular, the oscillating input signal may also be differentiated before it is fed to the mixer. For the provision of the differentiated oscillating input signal a further differentiation unit or element may be provided.

According to another exemplary embodiment the magnetoresistive sensor system further comprises a lowpass filter, wherein the lowpass filter is adapted to filter the mixed filtered signal.

The provision of a lowpass filter may be a suitable measure to suppress and/or eliminate distortions in an output signal of the magnetoresistive sensor system.

According to another exemplary embodiment of the magnetoresistive sensor system the magnetic field source is a coil.

In particular, the oscillating signal may be provided by an oscillator providing a driving signal for the coil. Specifically, the oscillating signal may be a sinusoidal signal.

The exemplary embodiments and aspects defined above and further aspects of the invention are apparent from the examples of embodiment to be described hereinafter and are explained with reference to these examples of embodiment. In particular, it should be noted that features which are described in connection with one exemplary embodiment or aspect may be combined with other exemplary embodiments and other exemplary aspects.

### BRIEF DESCRIPTION OF THE DRAWINGS

The invention will be described in more detail hereinafter with reference to examples of embodiment but to which the invention is not limited.

FIG. 1 schematically shows a simplified circuit diagram of a current fed anisotropic magnetoresistive (AMR) sensor.

FIG. 2 schematically shows superposition of a magnetic excitation and an external magnetic field.

FIG. 3 schematically shows phase modulated sensor signals.

FIG. 4 shows a schematically block diagram of elements of an analog processing unit.

FIG. 5 shows a schematically block diagram of a digital signal processing unit.

### DESCRIPTION OF EMBODIMENTS

The illustration in the drawing is schematically. In different drawings, similar or identical elements are provided with similar or the same reference signs.

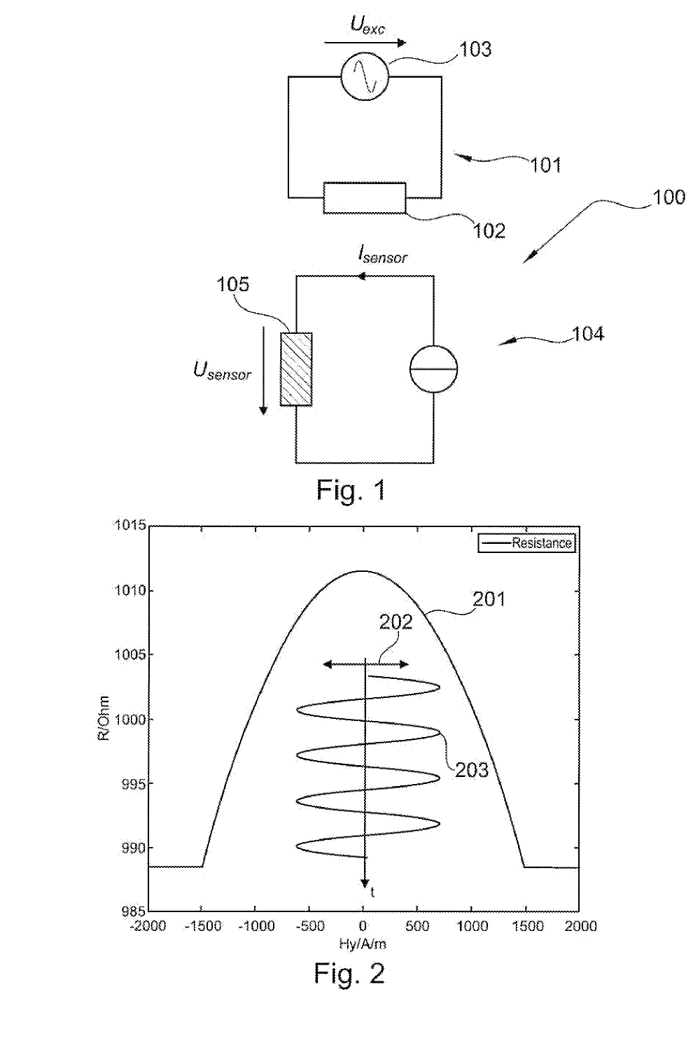

In the following, referring to FIGS. 1 to 5 some basic principles of a magnetoresistive sensor system according to an exemplary embodiment will be explained.

FIG. 1 shows a simplified circuit diagram of a current fed anisotropic magnetoresistive sensor (AMR sensor) 100 with sinusoidal excitation. In detail FIG. 1 shows a magnetic field source 101 comprising a drive coil 102 and a source 103 of an oscillating voltage, e.g. an oscillator. Furthermore, FIG. 1 shows a magnetoresistive sensor 104 comprising an AMR element 105. In particular, it should be noted that the easy axis of the AMR element 105 has a direction which is substantially vertical in FIG. 1, i.e. in the direction of the voltage Uₛₑₙₛₒᵣ indicated in FIG. 1, while the direction of the magnetic field induced by the drive coil 102 is substantially horizontally in FIG. 1, i.e. substantially parallel to the voltage U_{exc} indicated in FIG. 1. In particular, it should be noted that the AMR element 104 is a non-linearized AMR element, i.e. does not provide a linearized output signal as a Barber pole for example. The drive coil 102 generates a sinusoidal magnetic excitation in y-direction, i.e. in a direction orthogonal to the easy axis of the AMR element, commonly referred to as the x-direction.

For small magnetic fields H_{y} in y-direction or a negligible field in x-direction (Hₓ→0) AMR sensors without Barber poles can be described by

$${R}_{sensor} = {R}_{0} + Δ R ( 1 - {( \frac{{H}_{y}}{{H}_{0}} )}^{2} ) \qquad ( 2 )$$

wherein H₀ represents a constant comprising the so-called demagnetizing and anisotropic field. The excitation created by the drive coil is given by

H_{exc}(t)=Ĥ_{exc} sin(ω_{exc}t) (3)

wherein H_{exc} represents the excitation magnetic field induced by the drive coil and Ĥ_{exc} represents the amplitude of the same. The coil is driven by an oscillation voltage source or oscillatory circuit by a voltage according to the following equation:

u_{exc}(t)=Û_{exc} sin(ω_{exc}t). (4)

In the following the magnetic field which has to be measured is called the external field Hₑₓₜ, which remains constant for an adequate choice of ω_{exc}=2πf_{exc}. So we find the magnetic input signal of the AMR sensor:

H_{y}(t)=Hₑₓₜ+Ĥ_{exc} sin(ω_{exc}t) (5)

FIG. 2 schematically shows the superposition of the external magnetic field and the excitation magnetic field. In particular, FIG. 2 shows the resistance R in Ω over the field H_{y} in A/m as the line 201. Furthermore, the magnetic fields Hₑₓₜ(t) and H_{exc}(t) are schematically shown as lines 202 and 203, respectively. As mentioned above as H_{exc}(t) is used a sinusoidal excitation is used. As can be seen in FIG. 2 the resistance distribution is a symmetric distribution, i.e. the resistance is identical for −H_{y} and +H_{y}.

Starting from the equations (1) and (4) the resulting Rₛₑₙₛₒᵣ(t) can be calculated and represents an amplitude modulation of H_{exc} by Hₑₓₜ. If equation (5) is put into (2) and for R₀>>ΔR the following equation will be achieved:

$${R}_{sensor} ( t ) = {R}_{0} - Δ {R ( \frac{{H}_{ext} + {\hat{H}}_{exc} sin ( {ω}_{exc} t )}{{H}_{0}} )}^{2} . \qquad ( 6 )$$

For Iₛₑₙₛₑᵣ=const. the output of the sensor is given by:

$${u}_{sensor} ( t ) = {R}_{0} {I}_{sensor} - Δ {{RI}_{sensor} ( \frac{{H}_{ext} + {\hat{H}}_{exc} sin ( {ω}_{exc} t )}{{H}_{0}} )}^{2} . \qquad ( 7 )$$

From equation (7) follows:

$$\frac{d {u}_{sensor}}{d t} = - 2 {ω}_{exc} Δ {RI}_{sensor} {\hat{H}}_{exc} ( \frac{{H}_{ext} + {\hat{H}}_{exc} sin ( {ω}_{exc} t )}{{H}_{0}} ) cos ( {ω}_{exc} t ) . \qquad ( 8 )$$

The product of (8) and

$$\frac{d {u}_{exc}}{d t} = {ω}_{exc} {\hat{U}}_{exc} cos ( {ω}_{exc} t ) \qquad ( 9 )$$

leads to:

$$\begin{matrix}m ( t ) = \frac{d {u}_{sensor}}{d t} \frac{d {u}_{exc}}{d t} \\ = - {ω}_{exc}^{2} Δ {RI}_{sensor} {\hat{U}}_{exc} {\hat{H}}_{exc} ( \frac{{H}_{ext} + {\hat{H}}_{exc} sin ( {ω}_{exc} t )}{{H}_{0}^{2}} ) \\ ( 1 + cos ( 2 {ω}_{exct} ) ) .\end{matrix} \qquad ( 10 )$$

which corresponds to the signal after mixing of the time differentiated sensed signal and the time differentiated excitation signal.

After lowpass filtering with a cut-off frequency of approximately f_{exc} a signal u(t)

$$u ( t ) = - {ω}_{0}^{2} Δ {RI}_{sensor} {\hat{U}}_{exc} {\hat{H}}_{exc} ( \frac{{H}_{ext} + {\hat{H}}_{exc} sin ( {ω}_{exc} t )}{{H}_{0}^{2}} ) , \qquad ( 11 )$$

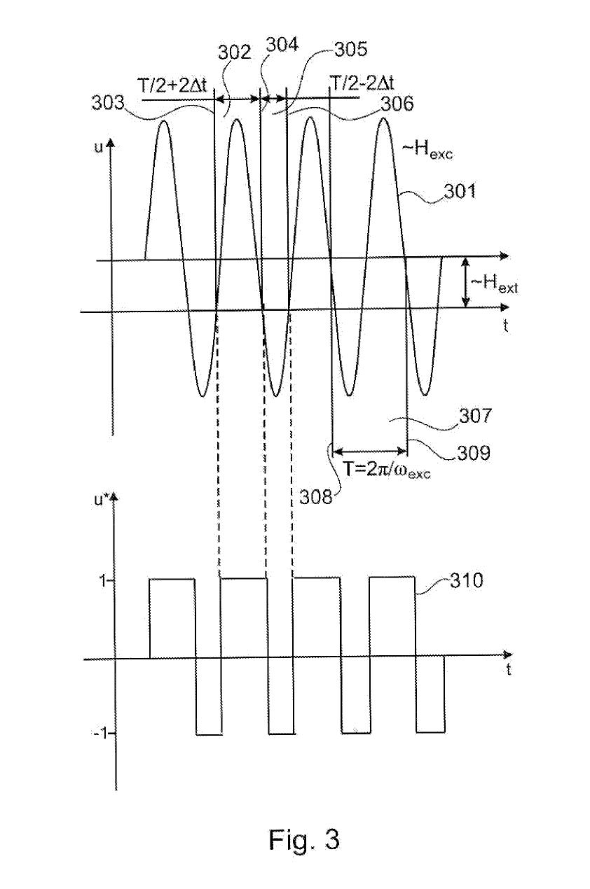

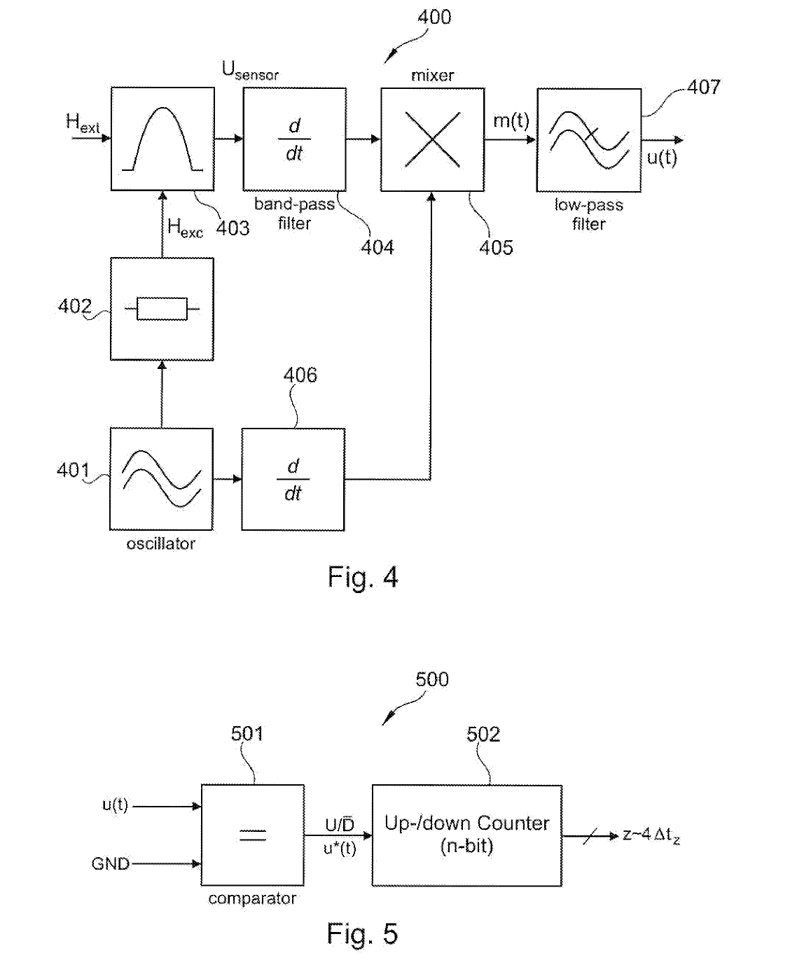

can be derived, which is shown in FIG. 3 and will be described in more detail later on. The signal u(t), which can be derived by a signal processing unit of a magnetoresistive sensor system shown in FIG. 4 has a zero crossing at

$${t}_{root} = \frac{1}{{ω}_{exc}} arcsin ( - \frac{{H}_{ext}}{{\hat{H}}_{exc}} ) , \qquad ( 12 )$$

which defines a change in the duty cycle of the corresponding signal

$$\begin{matrix}{u}^{*} ( t ) = \{ \begin{matrix}1 \\ - 1\end{matrix} for \begin{matrix}u ( t ) \geq 1 \\ u ( t ) < 1\end{matrix} \\ by & ( 13 ) \\ Δ t = \vert {t}_{root} \vert . & ( 14 )\end{matrix}$$

This means that for a positive external field Hₑₓₜ u(t) is positive for t=[0,T/2+2Δt] and negative for t=[T/2+2Δt,T] as shown in FIG. 3. So it is possible to define two time domains for a positive

$${t}_{postive} = \frac{T}{2} \pm 2 Δ t \qquad ( 15 )$$

and a negative

$${t}_{negative} = \frac{T}{2} ∓ 2 Δ t \qquad ( 16 )$$

signal u*(t). The difference of (15) and (16) is offset free and corresponds to the magnitude of the external field:

$${t}_{H} = {t}_{postive} - {t}_{negative} = 4 Δ t = 4 \vert arcsin ( - \frac{{H}_{ext}}{{H}_{exc}} ) \vert . \qquad ( 17 )$$

In order to get the time interval t_{H} an analog as well as a digital implementation is possible. Since digital signal processing has the advantage of an implicit analog-to-digital conversion, a digital realization is preferred.

The signals u(t) and u*(t) are depicted in FIG. 3. In detail in the upper part of FIG. 3 the signal u(t) is shown, i.e. the phase modulated mixed signal, which depends on H_{exc}, e.g. is proportional. Beside the sinusoidal signal labelled 301 some intervals are marked in FIG. 3. In detail these intervals are the interval of

$$\frac{T}{2} + 2 Δ t$$

labelled 302 and which lies between the lines 303 and 304, and

$$\frac{T}{2} - 2 Δ t$$

labelled 305 and which lies between the lines 304 and 306. A third interval 307 is depicted as well and corresponds to the period T=2π/ω_{exc} of the signal and which lies between the lines 308 and 309. Furthermore, the external signal Hₑₓₜ and which corresponds to a shift of the signal u(t) is depicted in FIG. 3.

In the lower part of FIG. 3 the corresponding signal u*(t) 310 is depicted, i.e. the signal corresponding to equation (13).

As already mentioned FIG. 4 schematically shows a block diagram of a signal processing unit which can be used to derive the signal u(t). In detail FIG. 4 shows a schematically block diagram of a portion of a magnetoresistive sensor system 400 according to an exemplary embodiment including a processing unit. The magnetoresistive sensor system comprises an oscillator 401 adapted to generate a driving signal, e.g. a sinusoidal voltage signal, which can be fed into a drive coil 402. The drive coil 402 generates an exciting magnet field H_{exc} which is superimposed to an external magnet field Hₑₓₜ to be measured. Furthermore, the magnetoresistive sensor system comprises a magnetoresistive sensor 403, e.g. an anisotropic magnetoresistive sensor or a giant magnetoresistive sensor, which measures the superimposed magnet field. It should be noted that the magnetoresistive sensor has an easy axis having a direction which is orthogonal to the direction of the exciting magnet field H_{exc}. An output signal of the magnetoresistive sensor 403 is a sensor voltage Uₛₑₙₛₒᵣ which is fed into a first differentiation unit 404. The differentiated signal of the magnetoresistive sensor 403 is then fed into a mixer 405 together with the sinusoidal voltage signal of the oscillator 401 which is also differentiated by a second differentiation unit 406. Afterwards, the mixed signal m(t) is fed into a lowpass filter 407 which generates the output voltage u(t).

FIG. 5 shows a schematically block diagram of a digital signal processing unit 500. The digital signal processing unit 500 comprises a comparator 501 into which the output signal u(t) is fed and compared with ground GND. Furthermore, the digital signal processing unit 500 comprises an up/down counter 502 into which an output signal of the comparator 501 is fed and which counts up for a positive u*(t) and down if u*(t) is negative. For a rising edge of U/ D̅ the counter output is valid and proportional to t_{H}. After that a reset of the counter is needed in order to prepare the next measurement. In particular, it should be mentioned that the sensitivity of the smart magnetoresistive sensor system only depends on the clock frequency of the digital counter.

Summarizing according to an exemplary aspect of the invention a magnetoresistive sensor system may be provided which is based on a non-linearized magnetoresistive sensor. In order to measure weak magnetic fields an exciting magnet field H_{exc} is used which is generated by using a sinusoidal signal and has a direction which is orthogonal to the easy axis of the magnetoresistive sensor. A differentiation element is used to process the output signal of the magnetoresistive sensor which is then mixed with the differentiated sinusoidal voltage signal of an oscillator and lowpass filtered in order to achieve a phase modulated output signal u(t).

It should be noted that the term “comprising” does not exclude other elements or features and the “a” or “an” does not exclude a plurality. Also elements described in association with different embodiments or aspects may be combined. It should also be noted that reference signs in the claims shall not be construed as limiting the scope of the claims.

1. A magnetoresistive sensor system to linearize a sensor transfer function comprising:
a magnetic field source,
a magnetoresistive sensor having an easy axis, and
a differentiation element,
wherein the magnetic field source is adapted to emit an auxiliary magnetic field generated from an oscillating input signal, wherein the auxiliary magnetic field is orthogonal to the easy axis of the magnetoresistive sensor,
wherein the magnetoresistive sensor is adapted to sense a signal associated to a superposition of an external magnetic field and the auxiliary alternating magnetic field, and
wherein the differentiation element is adapted to differentiate the sensed signal.

2. The magnetoresistive sensor system according to claim 1,
wherein the magnetoresistive sensor is an anisotropic magnetoresistive sensor and/or and giant magnetoresistive sensor.

3. The magnetoresistive sensor system according to claim 1, further comprising:
a mixer adapted to mix the differentiated signal and the oscillating input signal.

4. The magnetoresistive sensor system according to claim 4, further comprising:
a lowpass filter,
wherein the lowpass filter is adapted to filter the mixed filtered signal.

5. The magnetoresistive sensor system according to claim 1,
wherein the magnetic field source is a coil.

6. A method of processing a signal of a magnetoresistive sensor the method comprising:
generating an auxiliary magnetic field orthogonal to an easy axis of the magnetoresistive sensor,
sensing a signal associated to a superposition of an external magnetic field and the auxiliary alternating magnetic field, and
differentiate the sensed signal.

7. A program element, which, when being executed by a processor, is adapted to control or carry out a method according to claim 6.

8. A computer-readable medium, in which a computer program is stored which, when being executed by a processor, is adapted to control or carry out a method according to claim 6.
